(19) United States
(12) Patent Application Publication
(10) Pub. No.: US 2026/0052991 A1
(43) Pub. Date: Feb. 19, 2026

(54) SEMICONDUCTOR STRUCTURE

(71) Applicant: Taiwan Semiconductor Manufacturing Company, Ltd., Hsinchu (TW)

(72) Inventors: Chen-Shien CHEN, Hsinchu County (TW); Chi-Yen Lin, Tainan City (TW); Feng-Chang Hsu, Hsinchu County (TW); Yao-Chun Chuang, Hsinchu City (TW); Hsu-Hsien Chen, Hsinchu City (TW)

(73) Assignee: Taiwan Semiconductor Manufacturing Company, Ltd., Hsinchu (TW)

(21) Appl. No.: 18/805,436

(22) Filed: Aug. 14, 2024

(51) Int. Cl. H01L 23/58; H01L 23/544

(52) U.S. Cl. CPC H01L 23/585; H01L 23/544; H01L 2223/54426

(57) ABSTRACT

A semiconductor structure includes a circuit region, a seal ring region and at least one alignment mark. The seal ring region surrounds the circuit region and includes a seal ring corner region. The seal ring is disposed in the seal ring region, and includes a corner seal ring portion in the seal ring corner region. The corner seal ring portion divides the seal ring corner region into a plurality of sub-regions, and the at least one alignment mark is disposed in at least one of the sub-regions of the seal ring corner region.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), and package on package (PoP) devices. Some 3DICs are prepared by placing chips over chips on a semiconductor wafer level. The 3DICs provide improved integration density and other advantages, such as faster speeds and higher bandwidth, because of the decreased length of interconnects between the stacked chips. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure according to some embodiments.

FIG. 2A is a simplified top view of a semiconductor structure according to some embodiments, FIG. 2B is an enlarged view of an area of the semiconductor structure in FIG. 2A, and FIG. 2C is a three-dimensional view of an alignment mark in FIG. 2B.

FIG. 3A to FIG. 3F are respectively a schematic top view of an alignment mark according to some embodiments.

FIG. 4A to FIG. 4G are respectively a schematic top view of an alignment mark according to some embodiments.

FIG. 5A to FIG. 5C are respectively an enlarged view of an area of the semiconductor structure in FIG. 2A.

FIG. 6A to FIG. 6E are schematic cross-sectional views of various stages in a method of forming a semiconductor structure according to some embodiments.

FIG. 7A to FIG. 7E are simplified top views of various stages in a method of forming a semiconductor structure according to some embodiments.

FIG. 8 is a cross-sectional view of a semiconductor structure according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

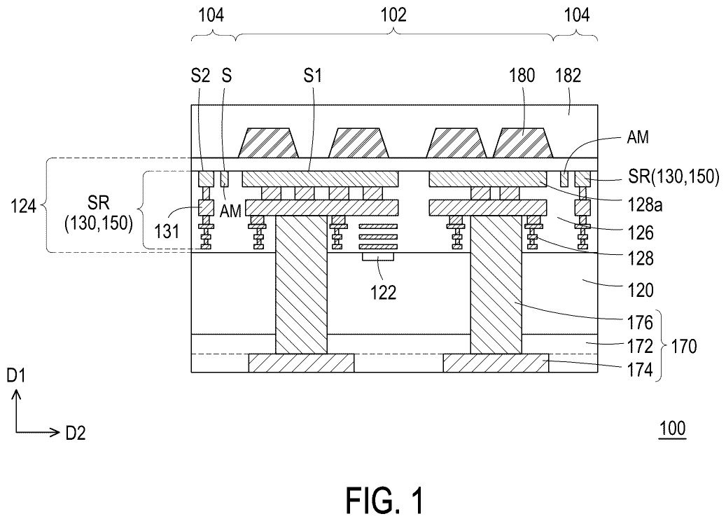

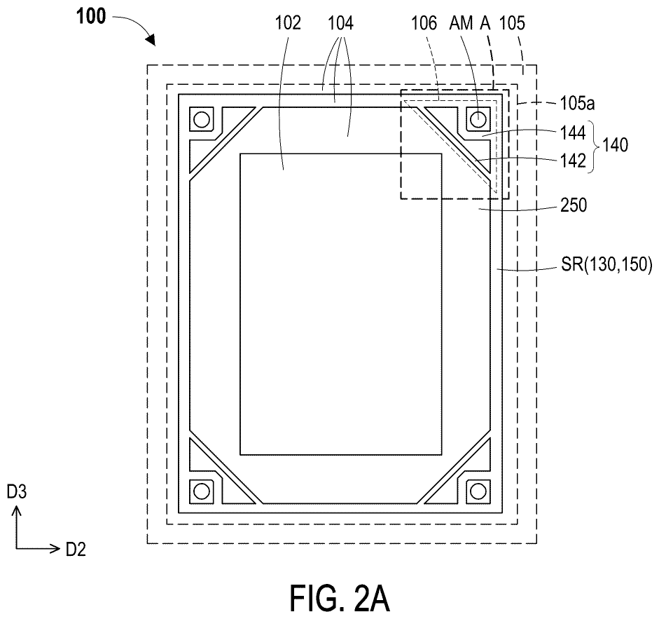

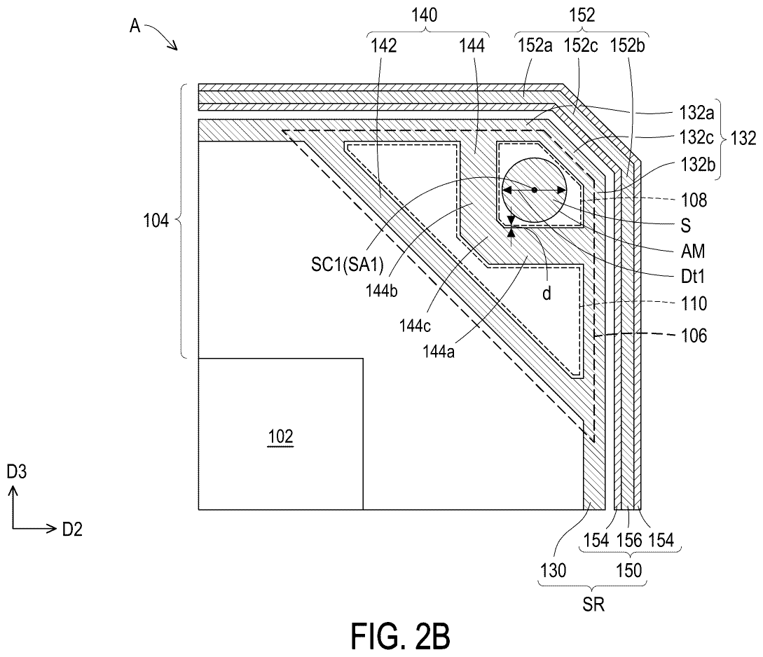

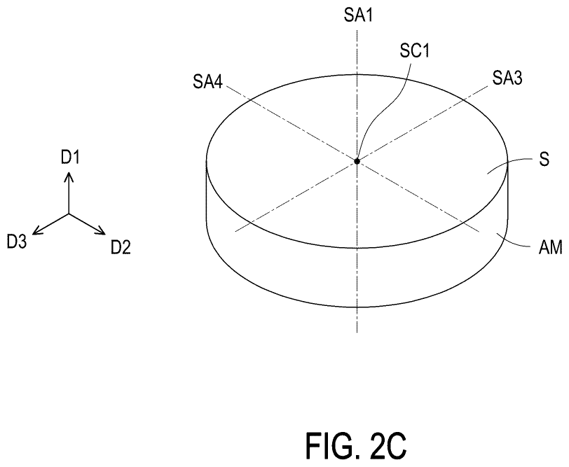

FIG. 1 is a cross-sectional view of a semiconductor structure according to some embodiments. FIG. 2A is a simplified top view of a semiconductor structure according to some embodiments, FIG. 2B is an enlarged view of an area of the semiconductor structure in FIG. 2A, and FIG. 2C is a three-dimensional view of an alignment mark in FIG. 2B.

Referring to FIG. 1 and FIG. 2A, a semiconductor structure includes an integrated circuit 100. The integrated circuit 100 includes a circuit region 102 and a seal ring region 104 surrounding the circuit region 102. The integrated circuit 100 may be a wafer-level structure (e.g., before dicing) or chip-level structure (e.g., after dicing). The circuit region 102 and the seal ring region 104 constitute a die region or chip region of the integrated circuit 100. For example, as illustrated in FIG. 2A, a scribe line region 105 surrounds the seal ring region 104, and the integrated circuit 100 is diced (or cut) along scribe lines 105a of the scribe line region 105. The seal ring region 104 may stay intact during the dicing process and provide sealing and protective functions to the circuit region 102. In some embodiments, the seal ring region 104 includes four seal ring corner regions 106 at corners of the seal ring region 104. The seal ring corner region 106 may be triangular shaped or substantially triangular shaped. For example, the periphery of the seal ring corner region 106 is substantially a right triangle or a right isosceles triangle. In some embodiments, one seal ring region 104 surrounds one circuit region 102. In alternative embodiments (not shown), the seal ring region 104 surrounds more than one circuit region 102.

The integrated circuit 100 may be a die such as an application-specific integrated circuit (ASIC) chip, an analog chip, a sensor chip, a wireless and radio frequency chip, a voltage regulator chip or a memory chip. As shown in FIG. 1, the integrated circuit 100 may include a semiconductor substrate 120, a device 122, an interconnect structure 124, a seal ring structure SR and alignment mark AM. The semiconductor substrate 120 and the interconnect structure 124 are stacked along a direction D1. The direction D1 is a vertical direction (e.g., Z direction), a direction D2 substantially perpendicular to the direction D1 is a horizontal direction (e.g., X direction), and a direction D3 (as shown in FIG. 2A) substantially perpendicular to both the direction D1 and the direction D2 is also horizontal direction (e.g., Y direction), for example. The semiconductor substrate 120 may be a semiconductor substrate such as a substrate of silicon, doped or undoped, or an active layer of a semiconductor-on-insulator (SOI) substrate. The semiconductor substrate 120 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 120 has a first side and a second side opposite to the first side. The first side is a front side (e.g., facing up in FIG. 1) and a second side is a backside (e.g., facing down in FIG. 1), for example.

In some embodiments, the semiconductor substrate 120 includes isolation structures (not shown) defining at least one active area, and a device layer is disposed on/in the active area. The device layer may include a variety of devices 122. The devices 122 are, for example, transistors, capacitors, resistors, diodes, photodiodes, fuse devices, or other similar devices. In some embodiments, the device 122 includes a gate structure, source/drain regions, spacers, and the like.

The interconnect structure 124 is disposed over the first side (e.g., front side) of the semiconductor substrate 120. Specifically, the interconnect structure 124 is electrically connected to the device layer within the circuit region 102. In some embodiments, the interconnect structure 124 includes at least one dielectric layer 126 and a plurality of conductive features 128. The conductive features 128 are disposed in the dielectric layer 126 and electrically connected with each other, for example. A portion of the conductive features 128, such as top conductive features 128a, are exposed by the dielectric layer 126. In some embodiments, the dielectric layer 126 includes an inter-layer dielectric (ILD) layer over the semiconductor substrate 120, and at least one inter-metal dielectric (IMD) layer over the inter-layer dielectric layer. In some embodiments, the dielectric layer 126 includes silicon oxide, silicon oxynitride, silicon nitride, a low dielectric constant (low-k) material or a combination thereof. The dielectric layer 126 may be a single layer or a multiple-layer structure. In some embodiments, the conductive features 128 include plugs and lines. The plugs may include contacts formed in the inter-layer dielectric layer, and vias formed in the inter-metal dielectric layer. The contacts are formed between and in contact with a bottom metal line and the device layer. The vias are formed between and in contact with two metal lines. The conductive features 128 may include tungsten (W), copper (Cu), a copper alloy, aluminum (Al), an aluminum alloy or a combination thereof. In some embodiments, a barrier layer (not shown) may be disposed between the conductive features 128 and the dielectric layer 126 to prevent the material of the conductive features 128 from migrating to the device layer. The barrier layer includes Ta, TaN, Ti, TiN, CoW or a combination thereof, for example. In some embodiments, the interconnect structure 124 is formed by multiple single damascene processes, a dual damascene process, an electroplating process or the like.

In some embodiments, as shown in FIG. 1, a bonding structure 170 is disposed below the interconnect structure 124 within the circuit region 102. In some embodiments, the bonding structure 170 includes at least one bonding dielectric layer 172 and a plurality of bonding conductive features. In some embodiments, the bonding dielectric layer 172 includes silicon oxide, silicon nitride, a polymer or a combination thereof. The bonding conductive features are disposed in the bonding dielectric layer 172 and electrically connected with each other. In some embodiments, the bonding conductive features include bonding vias 174 electrically connected to the interconnect structure 124 and bonding pads 176 electrically connected to the bonding vias 174. The bonding conductive features may include tungsten (W), copper (Cu), a copper alloy, aluminum (Al), an aluminum alloy or a combination thereof. In some embodiments, the bonding vias 174 further extend through the semiconductor substrate 120. Thus, the bonding vias 174 are also referred to as through-silicon vias (TSVs) or through-semiconductor vias (also TSVs). In some embodiments, a barrier layer (not shown) is disposed between the bonding conductive features and the bonding dielectric layer 172. The barrier layer includes Ta, TaN, Ti, TiN, CoW or a combination thereof, for example. In some embodiments, the bonding structure 170 is formed by multiple single damascene processes, a dual damascene process, an electroplating process or the like.

In some embodiments, the integrated circuit 100 includes a plurality of conductive pads 180 in a dielectric layer 182. The interconnect structure 124 is disposed between the semiconductor substrate 120 and the conductive pads 180, and the semiconductor substrate 120 is disposed between the bonding structure 170 and the interconnect structure 124, for example. The conductive pads 180 may be disposed adjacent to the top conductive features 128a and the alignment marks AM. The conductive pads 180 are aluminum pads, for example.

As shown in FIG. 2B, the seal ring structure SR includes seal rings 130, 150 over the first side (e.g., front side) of the semiconductor substrate 120. Specifically, the seal rings 130, 150 are disposed over and electrically insulated from the underlying device layer, and located aside the interconnect structure 124 within the seal ring region 104. In some embodiments, as shown in FIG. 1, the seal rings 130, 150 are formed during the formation of the interconnect structure 124. The seal rings 130, 150 may include stacks of dummy conductive features 131 such as dummy conductive lines and/or dummy conductive vias.

Herein, when elements are described as “at substantially the same level”, the elements are formed at substantially the same height in the same layer, or having the same positions embedded by the same layer. In some embodiments, the elements at substantially the same level are formed from the same material(s) with the same process step(s). In some embodiments, the tops of the elements at substantially the same level are substantially coplanar. For example, as shown in FIG. 1, the seal rings 130, 150 are at substantially the same level with the interconnect structure 124. Specifically, the surfaces (e.g., top surfaces) S2 of the seal rings 130, 150 are substantially coplanar with the surfaces (e.g., top surfaces) S1 of the top conductive features 128a of the interconnect structure 124.

Referring to FIG. 2B, the seal ring 130 includes a main portion 132 and four corner seal ring portions 140 at four interior corners of the main portion 132. The seal ring 130 is disposed in the seal ring region 104, and the four corner seal ring portions 140 are disposed in the seal ring corner regions 106. In some embodiments, the main portion 132 is a rectangular ring or a substantially rectangular ring, and an interior outline and an exterior outline of the main portion 132 respectively form a substantially rectangular periphery. For example, the main portion 132 include a first portion 132a extending along the direction D2, a second portion 132b extending along the direction D3 and a third portion 132c between the first portion 132a and the second portion 132b. The third portion 132c is a sloped portion, for example. In the illustrated embodiments, an interior outline (or interior boundary) of the seal ring 130 is octagonal or substantially octagonal.

In some embodiments, the corner seal ring portion 140 includes a bridge section 142 and an L-shaped section 144. The bridge section 142 may include a continuous linear feature and extend between a first edge (e.g., first portion 132a) and a second edge (e.g., second portion 132b) of the seal ring 130 (e.g., main portion 132). For example, a first connection part is formed between the bridge section 142 and the first portion 132a of the main portion 132, and a second connection part is formed between the bridge section 142 and the second portion 132b of the main portion 132. The L-shaped section 144 may also extend between the first edge (e.g., first portion 132a) and the second edge (e.g., second portion 132b) of the seal ring 130 (e.g., main portion 132). For example, a third connection part is formed between the L-shaped section 144 and the first portion 132a of the main portion 132, and a fourth connection part is formed between the L-shaped section 144 and the second portion 132b of the main portion 132. The third connection part is disposed between the third portion 132c of the main portion 132 and the first connection part, and the fourth connection part is disposed between the third portion 132c of the main portion 132 and the second connection part. The L-shaped section 144 is disposed between the seal ring 130 (e.g., main portion 132) and the bridge section 142, for example. The L-shaped section 144 has an “L” shape. For example, in FIG. 2B, the L-shaped section 144 include a first portion 144a extending along the direction D2, a second portion 144b extending along the direction D3 and a third portion 144c between the first portion 144a and the second portion 144b. The third portion 144c is a sloped portion and has the smallest distance to the bridge section 142, for example.

In some embodiments, the bridge section 142 and the L-shaped section 144 are separated from each other. However, the disclosure is not limited thereto. The bridge section 142 and the L-shaped section 144 may be connected each other by the third portion 144c. In some embodiments, both the L-shaped section 144 and bridge section 142 are connected to the seal ring 130 (e.g., main portion 132). In alternative embodiments, at least one of the L-shaped section 144 and the bridge section 142 is not connected to the seal ring 130 (e.g., main portion 132). The corner seal ring portion 140 may provide various mechanical benefits to the seal ring 130 (e.g., main portion 132), such as preventing layer peeling at the corner of the chips during dicing processes. In some embodiments, the main portion 132, the bridge section 142 and the L-shaped section 144 of the seal ring 130 are formed during the formation of the interconnect structure 124. The main portion 132, the bridge section 142 and the L-shaped section 144 may include stacks of dummy conductive lines and/or conductive vias. For example, the main portion 132, the bridge section 142 and the L-shaped section 144 of the seal ring 130 are at substantially the same level with the interconnect structure 124. Specifically, the surfaces (e.g., top surfaces) of the main portion 132, the bridge section 142 and the L-shaped section 144 of the seal ring 130 are substantially coplanar with the top surfaces S1 of the top conductive features 128a of the interconnect structure 124.

As shown in FIG. 2B, the seal ring corner region 106 is triangular shaped or substantially triangular shape, for example. The periphery of each seal ring corner region 106 may be substantially a right triangle or a right isosceles triangle. The corner seal ring portion 140 divides the seal ring corner region 106 into a plurality of sub-regions 108, 110. The sub-region 108 is disposed between the seal ring 130 (e.g., main portion 132) and the L-shaped section 144, and the sub-region 110 is disposed between the L-shaped section 144 and the bridge section 142, for example.

In some embodiments, the seal ring 150 is disposed in the seal ring region 104 to surround the seal ring 130. Thus, the seal ring 130 may be also referred to as the inner seal ring (e.g., innermost seal ring). The seal ring 130 and the seal ring 150 are concentric to each other, for example. Having multiple seal rings 130, 150 may ensure that at least the inner seal ring(s) is/are protected from cracks during dicing (e.g., die sawing). For example, the seal ring 150 protects the seal ring 130 from damages that may occur during dicing. In the illustrated embodiments, similar to the seal ring 130, the seal ring 150 includes a main portion 152 which is a rectangular ring or a substantially rectangular ring, and an interior outline and an exterior outline of the main portion 152 respectively form a substantially rectangular periphery. The main portion 152 of the seal ring 150 may also include a first portion 152a and a second portion 152b and a third portion (e.g., sloped portion) 152c between the first and second portions 152a and 152b. The first, second and third portions 152a, 152b and 152c of the seal ring 150 may be substantially parallel to the first, second and third portions 132a, 132b and 132c of the seal ring 130, respectively. The main portion 132 of the seal ring 130 is, for example, disposed between the corner seal ring portion 140 and the seal ring 150. In some embodiments, the seal ring 150 includes two sections 154 and a section 156 disposed between the two sections 154. The section 154 may be also referred to as a dummy metal section, and the section 156 may be also referred to as an aluminum pad section. In alternative embodiments, the seal ring 150 includes the section 156 and one section 154 disposed between the seal ring 130 and the section 156, or the seal ring 150 includes the section 156 only. The section 156 and the dummy metal section(s) 154 each includes first and second portions and a third portion (e.g., sloped portion) between the first and second portions.

As shown in FIG. 1, the alignment mark AM is disposed over the first side (e.g., front side) of the semiconductor substrate 120. Specifically, the alignment mark AM is disposed over and electrically insulated from the device layer, and located within the corner seal ring portion 140 and adjacent to the top conductive features 128a of the interconnect structure 124. In some embodiments, the alignment mark AM is at a floating potential. In some embodiments, the alignment mark AM is formed during the formation of the top conductive features 128a. For example, the alignment mark AM is at substantially the same level with the top conductive features 128a. Specifically, as shown in FIG. 1, the surface (e.g., top surface) S of the alignment mark AM are substantially coplanar with the top surface S1 of the top conductive feature 128a of the interconnect structure 124 and the top surface S2 of the seal ring 130. In some embodiments, the alignment mark AM includes metal, such as copper.

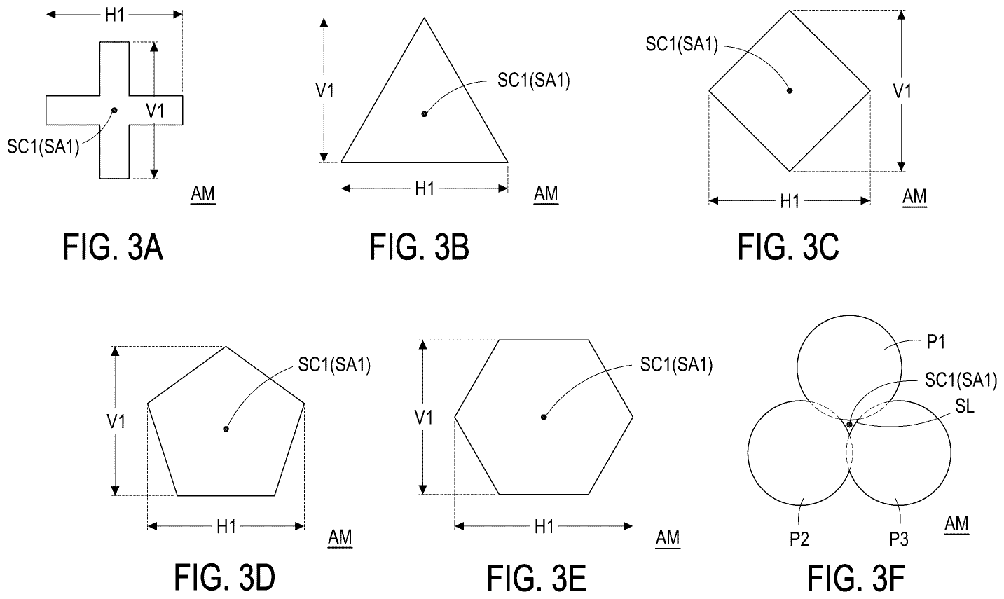

In some embodiments, as shown in FIG. 2B, the alignment mark AM is disposed in at least one of the sub-regions 108, 110 of the seal ring corner region 106. For example, the alignment mark AM is disposed in the sub-region 108. In some embodiments, the alignment mark AM is separated from the seal ring 130 (e.g., corner seal ring portion 140) by a distance d. In other words, from a top view, the alignment mark AM is non-overlapped with the corner seal ring portion 140, for example. The distance d is larger than about 1.3μm, for example. From a top view, the alignment mark AM is a circle (as shown in FIG. 2B), a cross (as shown in FIG. 3A), a polygon (e.g., a triangle (as shown in FIG. 3B), a rectangle (as shown in FIG. 3C), a pentagon (as shown in FIG. 3D) and a hexagon (as shown in FIG. 3E)), a flower-like shape (as shown in FIG. 3F) or the like. In an embodiment in which the alignment mark AM includes a circle (as shown in FIG. 2B) or a substantial circle, a dimension (e.g., a diameter Dt1) of the alignment mark AM is about 5μm to about 100μm. In FIG. 3A to FIG. 3F in which the alignment mark AM is a cross or a polygon, a dimension (e.g., vertical length V1 and horizontal length H1) is about 5μm to about 100μm. If the dimension (e.g., diameter Dt1, vertical length V1 and horizontal length H1) of the alignment mark AM is equal to or larger than 40μm, the alignment accuracy may be improved. On contrary, if the dimension (e.g., diameter Dt1, vertical length V1 and horizontal length H1) of the alignment mark AM is smaller than 40μm, the alignment accuracy may be lowered.

The alignment mark AM may include a symmetrical shape having a symmetrical axis (e.g., the alignment mark AM is symmetrical with the symmetrical axis) or a non-symmetrical shape. Herein, the symmetrical axis is an axis passing through a symmetrical center of the symmetrical shape. The symmetrical axis is substantially perpendicular to a surface of the alignment mark AM, for example. In some embodiments, as shown in FIG. 2B and FIG. 2C, the alignment mark AM include a symmetrical shape such as circle, and the alignment mark AM has a symmetrical axis SA1. The symmetrical axis SA1 passes through a symmetrical center SC1 of the alignment mark AM and substantially perpendicular to a surface S1 of the alignment mark AM, and the alignment mark AM is symmetrical with the symmetrical axis SA1, for example. In some embodiments, as shown in FIG. 2C, the symmetrical axis SA1 extends along a direction substantially parallel to a stacked direction (e.g., the direction D1 (e.g., Z direction)) of the semiconductor substrate 120 and the interconnect structure 124, and the symmetrical axis SA1 is substantially perpendicular to the surface S1 (e.g., extending along the directions D2 and D3 (e.g., X-Y plane)) of the alignment mark AM. As shown in FIG. 1, the surface S1 of the alignment mark AM is substantially coplanar with the surface S2 of the top conductive features 128a of the interconnect structure 124. As shown in FIG. 3A to FIG. 3F, the alignment mark AM include a symmetrical shape such as regular polygon and flower-like shape, and thus the alignment mark AM has a symmetrical axis SA1 passing through a symmetrical center SC1. In the illustrated FIG. 3A to FIG. 3F (and also FIG. 2B), the direction of the symmetrical axis SA1 is a direction that goes into and out of the paper. In some embodiments in which the alignment mark AM include a symmetrical shape as shown in FIG. 3A to FIG. 3F, the vertical length V1 and the horizontal length H1 of the alignment mark AM are substantially the same. In alternative embodiments, the alignment mark AM has a non-symmetrical shape such as an irregular polygon, and the vertical length V1 and the horizontal length H1 of the alignment mark AM are different. In some embodiments, as shown in FIG. 3F, the alignment mark AM includes a plurality of portions P1, P2, P3 with identical symmetrical shape such as circle or regular polygon, and the portions P1, P2, P3 are partially overlapped and partially non-overlapped in a top view. For example, the partially overlapped portions P1, P2, P3 form the alignment mark AM and have a symmetrical axis SA1. In such embodiment, the alignment mark AM may have a slot (e.g., a hollow or an opening) SL therein. The slot SL may be non-filled, partially fill or fully filled by a suitable material during and/or after the formation process of the alignment mark AM according to the size of the slot SL and/or the filling capacity of the material. For example, the slot SL is partially or fully filled by the dielectric layer 126 of the interconnect structure 124, and a dielectric pattern (not shown) is formed within the alignment mark AM. In some embodiments, as shown in FIG. 2C, the alignment mark AM may include at least two symmetrical axes SA3, SA4 parallel to the surface S1 of the alignment mark AM. Similarly, the shape of FIG. 3A to FIG. 3F or the like may include at least two symmetrical axes (not shown) parallel to the surface S1 of the alignment mark AM.

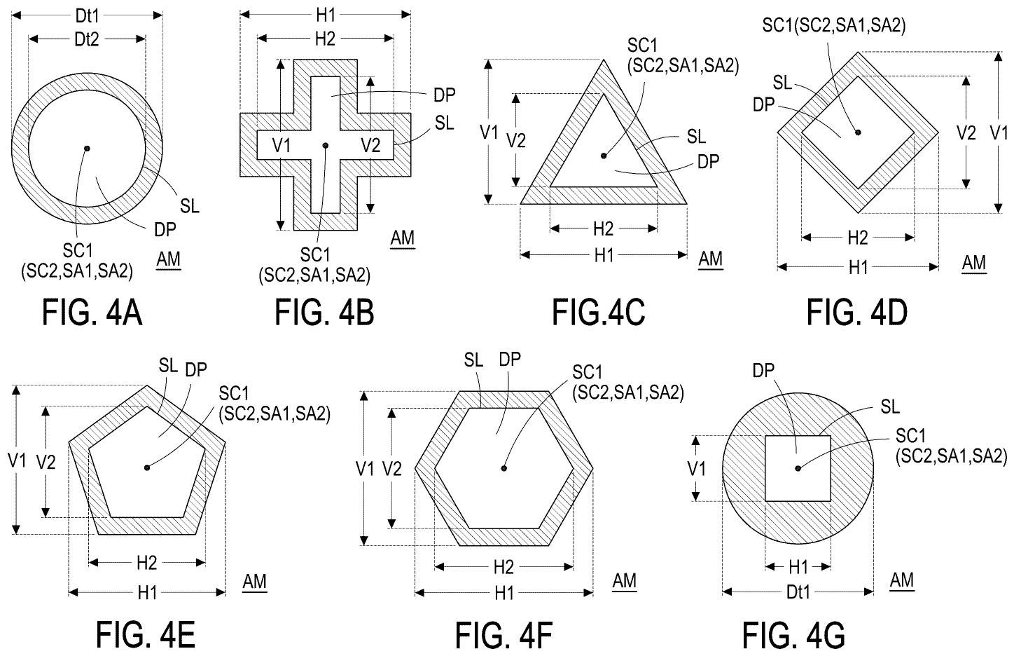

In some embodiments, the alignment mark AM is a solid pattern. However, the disclosure is not limited thereto. The alignment mark AM may be ring-shaped, that is, the alignment mark AM includes a slot (e.g., a hollow or an opening) SL therein. From a top view, as shown in FIG. 4A to FIG. 4F, the alignment mark AM includes a slot (e.g., a hollow or an opening) SL. The slot SL is a circle (as shown in FIG. 4A), a polygon such as a cross (as shown in FIG. 4B), a polygon (e.g., a triangle (as shown in FIG. 4C), a rectangle (as shown in FIG. 4D), a pentagon (as shown in FIG. 4E) and a hexagon (as shown in FIG. 4F)) or the like. In an embodiment in which the slot SL is a circle (as shown in FIG. 4A) or a substantial circle, a dimension (e.g., a diameter Dt2) of the slot SL is smaller than a dimension (e.g., a diameter Dt1) of the alignment mark AM, and the dimension (e.g., the diameter Dt2) is about 5μm to about 100μm. In FIG. 4B to FIG. 4F in which the slot SL is a cross or a polygon, a dimension (e.g., vertical length V2 and horizontal length H2) is smaller than a dimension (e.g., vertical length V1 and horizontal length H1) of the alignment mark AM, and the dimension (e.g., vertical length V2 and horizontal length H2) is about 5μm to about 100μm. In some embodiments, the slot SL has a symmetrical shape having a symmetrical axis SA2 (e.g., the slot SL is symmetrical with the symmetrical axis SA2) or a non-symmetrical shape. As shown in FIG. 4A to FIG. 4F, the slot SL is a circle or a regular polygon, and thus the slot SL has a symmetrical axis SA2 passing through a symmetrical center SC2. For example, the symmetrical axis SA2 is overlapped with the symmetrical axis SA1, and the symmetrical center SC2 is overlapped with the symmetrical center SC1. In some embodiments, as shown in FIG. 4B to FIG. 4F, the slot SL has a symmetrical shape such as a regular polygon, the vertical length V2 and the horizontal length H2 of the slot SL are the same. In alternative embodiments, the slot SL has a non-symmetrical shape such as an irregular polygon, and the vertical length V2 and the horizontal length H2 of the slot SL are different. In some embodiments, the slot SL has a shape the same as or similar to a shape (e.g., an exterior outline) of the alignment mark AM. In alternative embodiments, as shown in FIG. 4G, the slot SL has a shape different from a shape (e.g., an exterior outline) of the alignment mark AM. For example, the alignment mark AM is a circle, and the slot SL is a rectangle. In such embodiments, the symmetrical axis SA2 of the slot SL may be overlapped with the symmetrical axis SA1 of the alignment mark AM or not.

The slot SL may be non-filled, partially fill or fully filled by a suitable material during and/or after the formation process of the alignment mark AM according to the size of the slot SL and/or the filling capacity of the material. For example, as shown in FIG. 4A to FIG. 4G, the slot SL is partially or fully filled by the dielectric layer 126 of the interconnect structure 124, and a dielectric pattern DP is formed within the alignment mark AM. The dielectric pattern DP has a shape the same as the slot SL, and the alignment mark AM may surround the dielectric pattern DP.

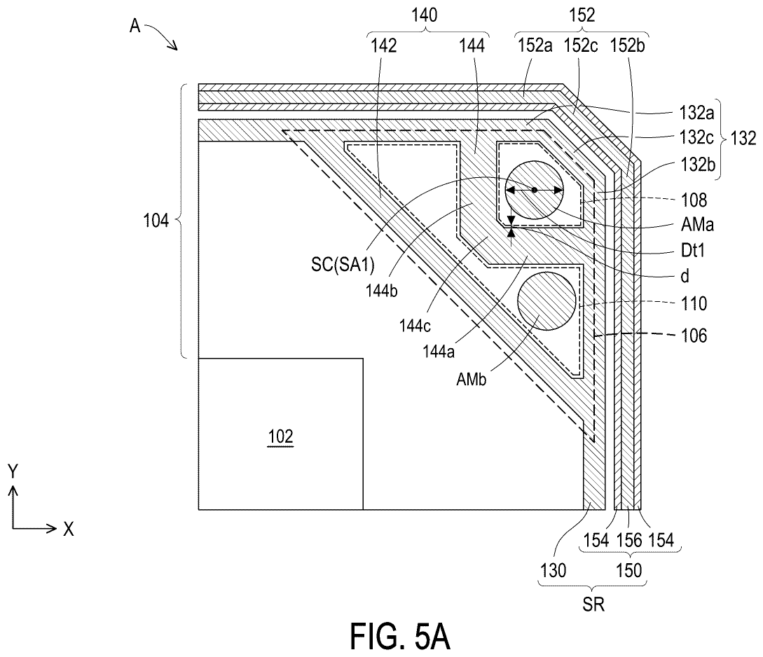

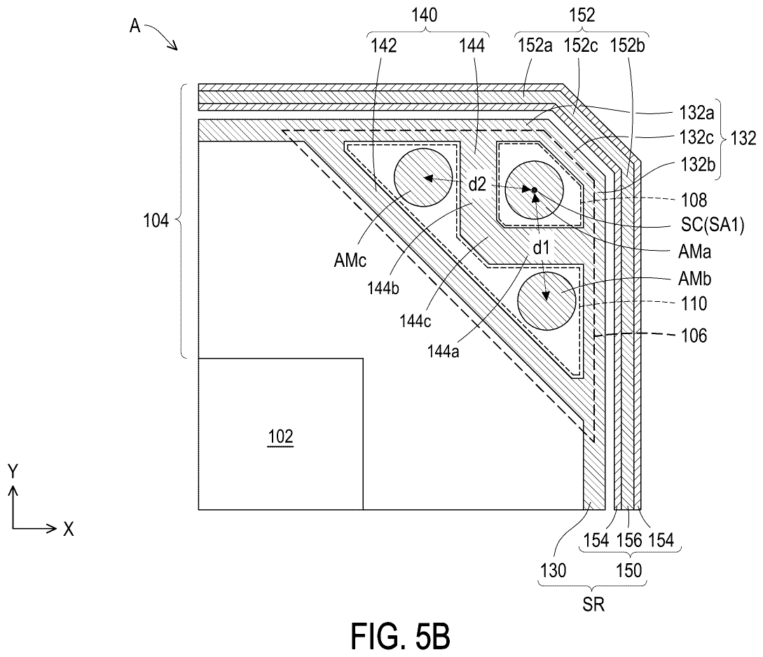

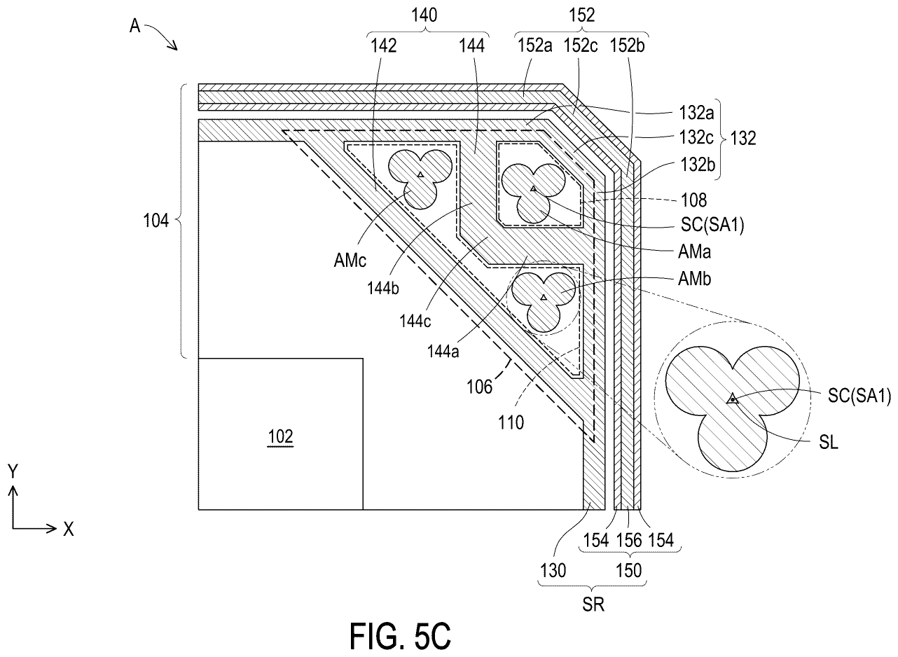

In some embodiments, only one alignment mark AM is illustrated in the seal ring corner region 106. However, the disclosure is not limited thereto. There may be more than one alignment mark AM in the seal ring corner region 106, and there may be more than one alignment mark AM in one sub-region 108, 110 of the seal ring corner region 106. In some embodiments, as shown in FIG. 5A, the alignment marks AMa, AMb are respectively disposed in the sub-regions 108, 110, and the alignment marks AMa, AMb are separated from each other by the seal ring 130. For example, the alignment mark AMa is disposed in the sub-region 108, and the alignment mark AMb is disposed in the sub-region 110, and alignment marks AMa, AMb are separated by the L-shaped section 144 therebetween. In some embodiments, as shown in FIG. 5B and FIG. 5C, a plurality of alignment marks AMa, AMb, AMc are disposed in the seal ring corner region 106, and the alignment marks AMa, AMb, AMc are separated from each other by the seal ring 130 (e.g., L-shaped section 144). As shown in FIG. 5B and FIG. 5C, one alignment mark AMa is disposed in the sub-region 108 and at least two alignment marks AMb, AMc are disposed in the sub-region 110. In some embodiments, the alignment marks AMa, AMb, AMc are arranged, so that a distance between the alignment marks AMa, AMb is substantially equal to a distance between the alignment marks AMa, AMc. For example, a distance d1 between centers of the alignment marks AMa, AMb is substantially equal to a distance d2 between the alignment marks AMa, AMc. Although the alignment marks AMa, AMb, AMc in FIG. 5B and FIG. 5C are illustrated as having identical shape, the alignment marks AMa, AMb, AMc may have different shapes, dimensions, arrangement or the like.

In some embodiments, a structure (not shown) is disposed at an exterior corner of the seal ring SR. For example, the structure is disposed at an exterior corner of the outermost seal ring 150 and separated from the seal ring 150. The structure may be disposed adjacent to the third portion (e.g., sloped portion) of the seal ring 150.

In some embodiments, the alignment mark is used for improved alignment accuracy (e.g., pick-and-place accuracy). For example, the alignment mark is detected using an imaging device mounted on an alignment apparatus, before the bonding process between a die having the alignment mark and a carrier or a top die and a bottom die having the alignment mark. Specifically, when two layers, elements or dies are bonded with one another, the alignment marks may be used to improve the alignment accuracy. For example, a reference position (e.g., physical center) of the integrated circuit may be determined by the symmetrical axes of the alignment marks. Then, the alignment accuracy may be calculated based on the reference position (e.g., physical center) of the integrated circuit. Thus, an overlay shift may be avoided and/or predictable. However, the disclosure is not limited thereto. The alignment accuracy may be determined by any other suitable method based on the alignment marks of the integrated circuit 100 according to the algorithm used by the detection method and/or detection device. In some embodiments, more symmetrical axes obtained from the alignment marks may improve the alignment accuracy. In some embodiments, the alignment mark may be detected using an imaging device mounted on an exposing apparatus, before the exposing process of a resist layer for defining patterns is carried out. In such embodiments, the alignment mark is also referred to an overlay mark.

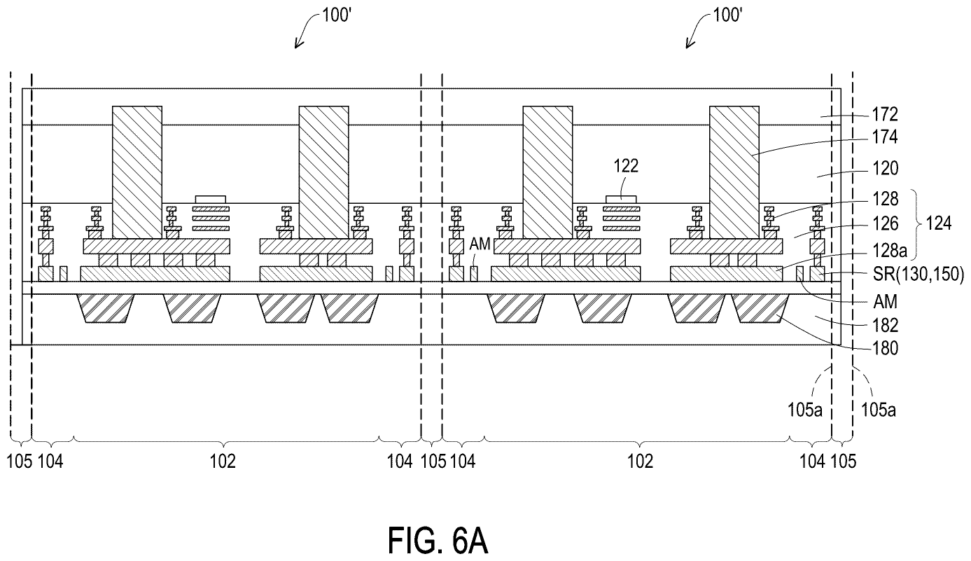

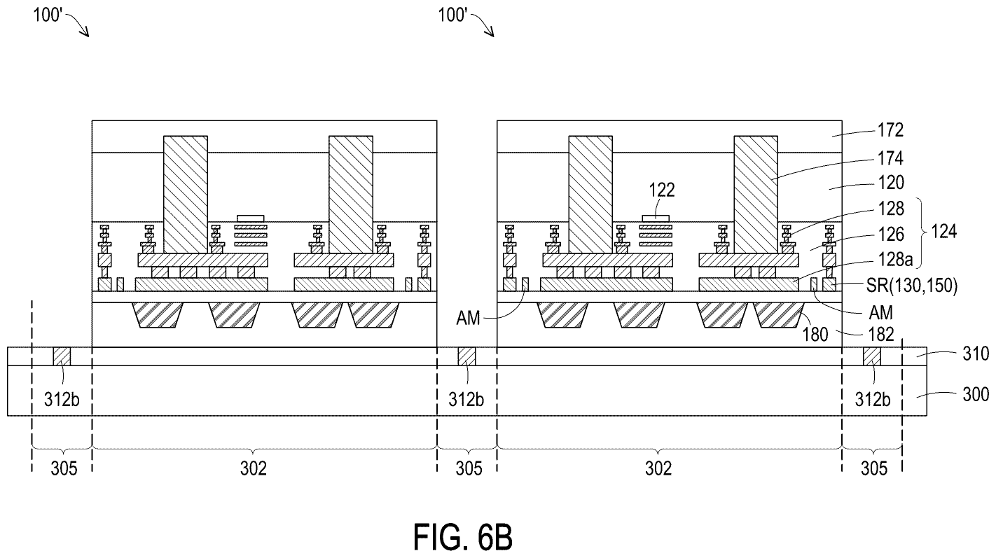

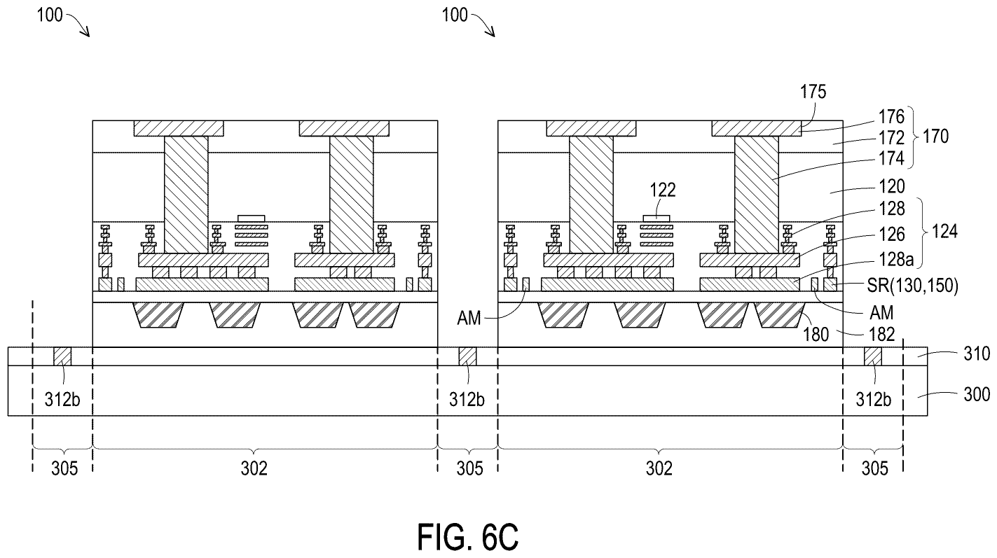

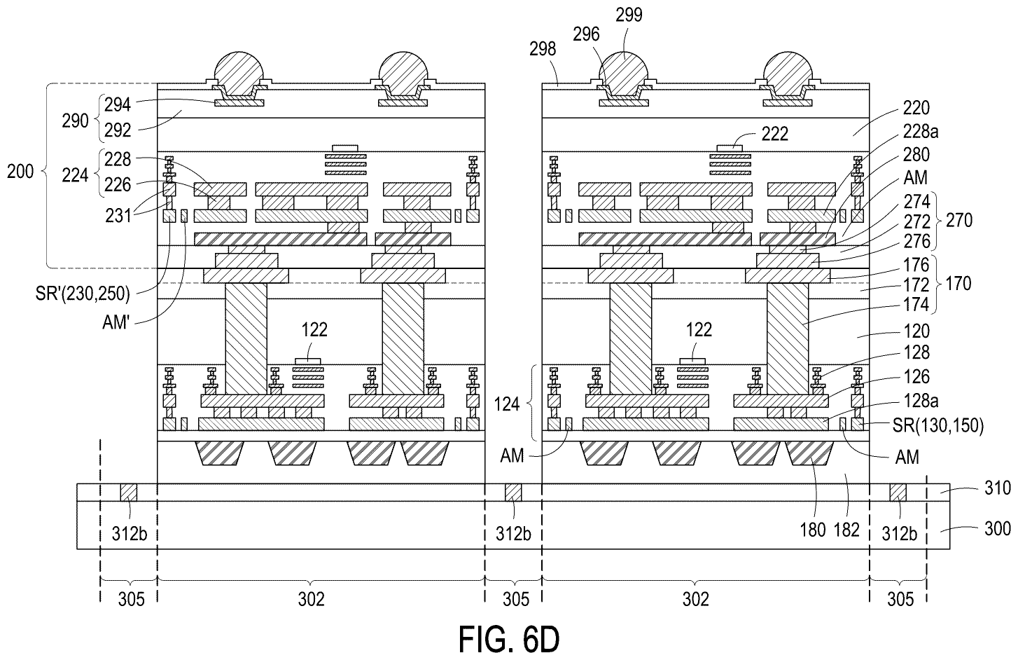

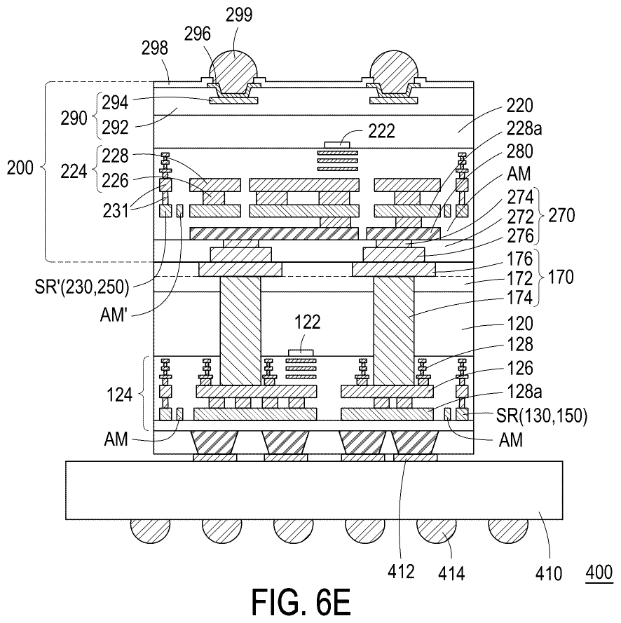

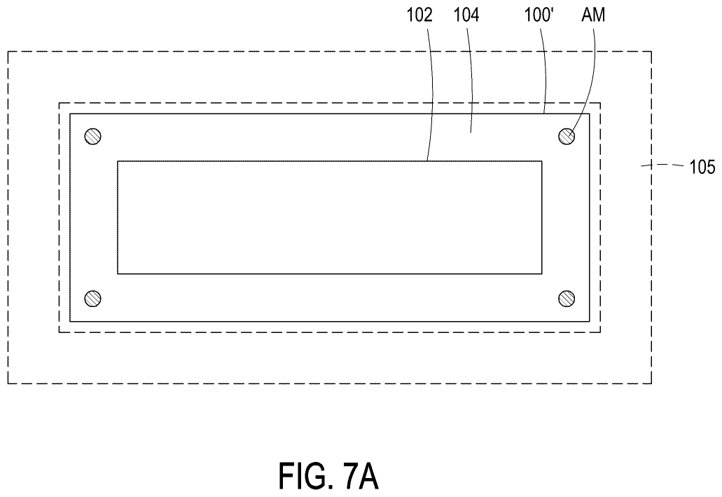

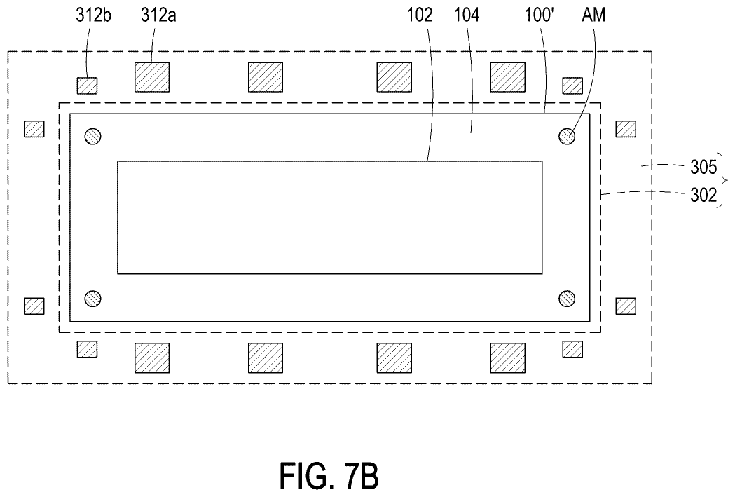

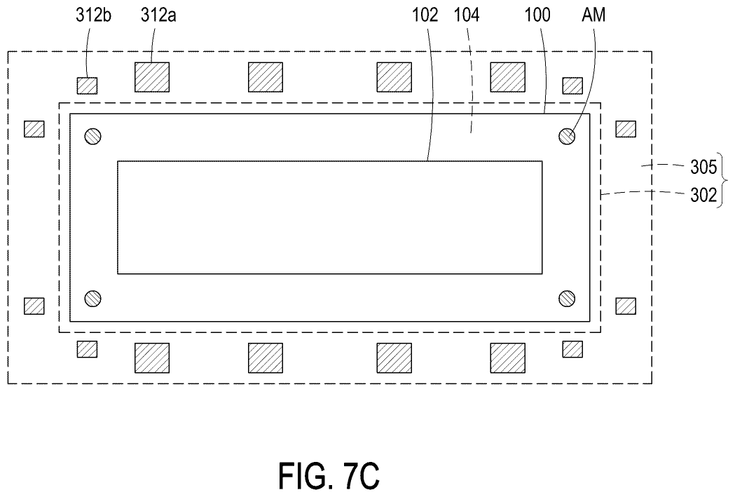

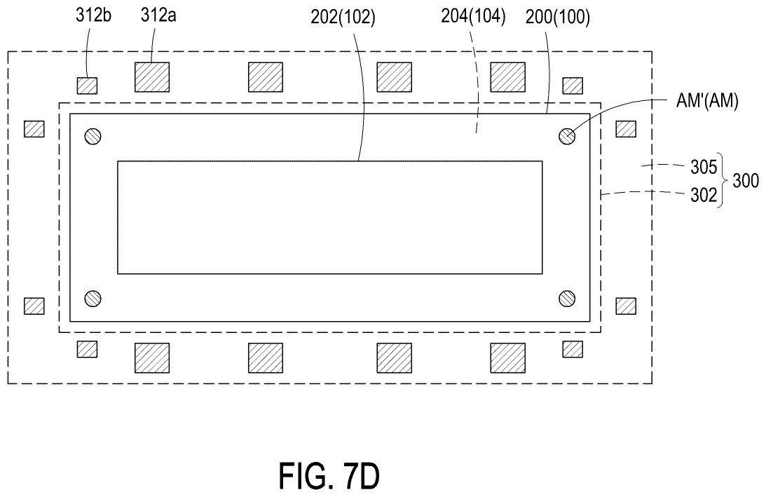

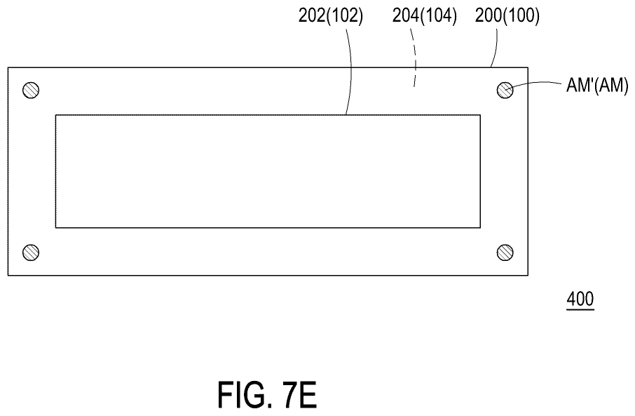

FIG. 6A to FIG. 6E are schematic cross-sectional views of various stages in a method of forming a semiconductor structure according to some embodiments. FIG. 7A to FIG. 7E are simplified top views of various stages in a method of forming a semiconductor structure according to some embodiments. For clarity, some elements are omitted in FIG. 7A to FIG. 7E.

Referring to FIG. 6A and FIG. 7A, a semiconductor structure is singulated along scribe lines 105a of scribe line regions 105, to form a plurality of integrated circuits 100′. FIG. 7A is similar to FIG. 2B, so the detailed description thereof is omitted herein. In some embodiments, the structure of the integrated circuit 100′ is similar to the structure of the integrated circuit 100 of FIG. 1, and the main difference lies in that the bonding structures 170 are not completely formed (e.g., the bonding pads 176 are not formed) in the integrated circuit 100′. In some embodiments, the integrated circuit 100′ includes bonding vias 174 in the semiconductor substrate 120 and a bonding dielectric layer 172 on the semiconductor substrate 120. For example, top surfaces of the bonding vias 174 are covered by the bonding dielectric layer 172. In some embodiments, the bonding vias 174 are initially embedded in the semiconductor substrate 120, and a thinning process is performed on the semiconductor substrate 120 to expose the bonding vias 174. Then, the semiconductor substrate 120 is recessed to form recesses, and some portions (the illustrated top portions) of the bonding vias 174 protrude beyond the semiconductor substrate 120 as shown in FIG. 6A. After that, the bonding dielectric layer 172 is formed to cover the bonding vias 174, so that the bonding vias 174 are embedded in the bonding dielectric layer 172, for example. However, the disclosure is not limited thereto. In alternative embodiments, the bonding dielectric layer 172 is not formed after the thinning process, and thus the bonding vias 174 are exposed by protruding from the semiconductor substrate 120 or being substantially coplanar with the semiconductor substrate 120. In alternative embodiments, a planarization process is further performed on the bonding dielectric layer 172 until the bonding vias 174 are exposed, and thus the top surfaces of the bonding vias 174 are substantially coplanar with the bonding dielectric layer 172.

In some embodiments, a singulation process is performed on the semiconductor structure along the scribe lines 105. The singulation process may include a plasma dicing, sawing, etching, the like, or a combination thereof. In some embodiments, the alignment mark AM may be used to increase accuracy during the singulation process.

Referring to FIG. 6B and FIG. 7B, the integrated circuits 100′ are bonded to a carrier 300. For example, the carrier 300 is provided, and a release layer 310 is formed on the carrier 300. In some embodiments, the carrier 300 is a blanket carrier wafer, which may be a glass carrier, a ceramic carrier, an organic carrier, or the like for carrying a semiconductor wafer or a reconstituted wafer for the manufacturing method of the package structure. The release layer 310 may include a dielectric material (e.g., a buried oxide layer), a polymer-based material (e.g., a Light To Heat Conversion (LTHC) material) which may be decomposed under the heat of a high-energy light, an epoxy-based thermal-release material, or the like. In some embodiments, the release layer 310 is dispensed as a liquid and cured. In alternative embodiments, the release layer 310 is a laminate film and is laminated onto the carrier 300. The top surface of the release layer 310 may be leveled and have a high degree of co-planarity. The release layer 310 may include a plurality of alignment marks 312a, 312b therein for improved alignment control. The alignment marks 312a, 312b are formed by forming openings in the release layer 310, for example, using a laser process or a lithography process. In alternative embodiments, a dielectric layer is further formed over the release layer 310. The dielectric layer may include one or more layers of photo-patternable dielectric materials and/or non-photo-patternable dielectric materials. The photo-patternable dielectric materials may be polybenzoxazole (PBO), polyimide (PI), benzocyclobutene (BCB), or the like, and may be formed using a spin-on coating process, or the like. Such photo-patternable dielectric materials may be easily patterned using similar photolithography methods as a photoresist material. The non-photo-patternable dielectric materials may be silicon nitride, silicon oxide, phosphosilicate glass (PSG), borosilicate glass (BSG), boron-doped phosphosilicate glass (BPSG), or the like, and may be formed using CVD, PVD, ALD, a spin-on coating process, the like, or a combination thereof.

The integrated circuits 100′ may be bonded to the carrier 300 by a pick-and-place process using a pick-and-place apparatus. In some embodiments, the carrier 300 includes a plurality of integrated circuit bonding regions 302 and scribe line regions 305 between the integrated circuit bonding regions 302. In some embodiments, the alignment marks 312a, 312b are arranged in the scribe line regions 305. The integrated circuits 100′ are respectively bonded to the integrated circuit bonding regions 302, for example. The scribe line regions 305 surround the integrated circuit bonding regions 302 and thus surround the bonded integrated circuits 100′. In other words, the alignment marks 312a, 312b are arranged along the periphery of the integrated circuit 100′. In some embodiments, the integrated circuits 100′ and the carrier 300 may be bonded through a fusion bonding. For example, the dielectric layer 126 of the integrated circuit 100′ and the release layer 310 over the carrier 300 are bonded through fusion bonding. If a dielectric layer is disposed between the integrated circuit 100′ and the release layer 310, a fusion bonding may be formed between the dielectric layer 126 of the integrated circuit 100′ and the dielectric layer. In alternative embodiments, the integrated circuit 100′ is bonded to the carrier 300 an adhesive layer such as an LTHC material, a UV adhesive, a die attach film, or the like.

In some embodiments, the alignment marks 312a, 312b surround the integrated circuit 100′. The alignment marks 312a are disposed at the corners of the integrated circuit 100′, and the alignment marks 312b are disposed along sides of the integrated circuit 100′, for example. The alignment marks 312a and the alignment marks 312b may have the same shape or different shapes. In some embodiments, the alignment mark 312a has a dimension smaller than the alignment mark 312b. However, the disclosure is not limited thereto. In some embodiments, the alignment marks 312a are used by the pick-and-place apparatus during the pick-and-place process to properly align the integrated circuits 100′ and the carrier 300. The alignment marks 312a may be used for alignment accuracy (e.g., pick-and-place accuracy), and thus the alignment marks 312a are also referred to as pick-and-place alignment marks. The alignment marks 312b may be detected by an overlay monitor to perform the overlay measurement after bonding, and thus the alignment marks 312b may be also referred to as overlay alignment marks.

In some embodiments, the alignment marks AM of the integrated circuit 100′ are also used for improved alignment accuracy (e.g., pick-and-place accuracy). The alignment marks AM of the integrated circuit 100′ may be used by the pick-and-place apparatus during the pick-and-place process to properly align the integrated circuits 100′ and the carrier 300. For example, the alignment marks 312a are detected to determine a reference position (e.g., pick-and-place center considered by the pick-and-place apparatus) of the integrated circuit bonding region 302, and the alignment marks AM are detected to determine a reference position (e.g., physical center) of the integrated circuit 100′. Then, the alignment accuracy may be calculated based on a difference between the determined reference position (e.g., pick-and-place center) of the integrated circuit bonding region 302 and the determined reference position (e.g., physical center) of the integrated circuit 100′. Thus, an overlay shift may be avoided, reduced and/or predictable. However, the disclosure is not limited thereto. The alignment accuracy may be determined by any other suitable method based on the alignment marks AM of the integrated circuit 100′ according to the algorithm used by the detection method and/or detection device. In some embodiments, by using the alignment marks AM and/or the alignment marks 312a, undesired shift of the integrated circuits 100′ may be reduced or avoided. Moreover, damage of the integrated circuits 100′ due to misalignment may be reduced or avoided.

Referring to FIG. 6C and FIG. 7C, a plurality of bonding pads 176 are formed on the bonding vias 174 respectively. In some embodiments, during the formation of the bonding pads 176, the alignment marks AM of the integrated circuit 100′ are used, so that the formed bonding pads 176 are aligned with the bonding vias 174 of the integrated circuits 100′. For example, a plurality of openings 171 are formed in the bonding dielectric layer 172 by a patterning process including an exposing process, and then the bonding pads 176 are formed in the openings 171 of the bonding dielectric layer 172. The alignment marks AM of the integrated circuit 100′ may be detected by an imaging device mounted on an exposing apparatus used during the exposing process. The bonding pads 176 may be then formed in the patterns 171 by a deposition process or the like. However, the disclosure is not limited thereto. The bonding pads 176 may be formed by any suitable process by the use of the alignment marks AM of the integrated circuit 100′.

In some embodiments, as shown in FIG. 6C, the bonding pads 176 are aligned with the bonding vias 174 therebelow, and thus the bonding pads 176 are electrically connected to the bonding vias 174. For example, a center line of the bonding pad 176 is aligned with a center liner of the respective bonding via 174. In some embodiments, the alignment marks AM of the integrated circuits 100′ are also referred to as overlay marks. In some embodiments, by using the alignment marks AM during the bonding process of the integrated circuit 100′ and the carrier 300 and/or the formation of the bonding pads 176 of the integrated circuit 100′, undesired shift may be reduced or avoided. Moreover, damage such as failure electrical connection due to the misalignment between the bonding vias 174 and the bonding pads 176 may be reduced or avoided. In some embodiments, after forming the bonding pads 176, an integrated circuit 100 is formed.

Referring to FIG. 6D and FIG. 7D, an integrated circuit 200 is bonded to the integrated circuit 100. The integrated circuit 200 may be a die such as an application-specific integrated circuit (ASIC) chip, an analog chip, a sensor chip, a wireless and radio frequency chip, a voltage regulator chip or a memory chip. The integrated circuit 200 and the integrated circuit 100 may be the same type of dies or different types of dies. In some embodiments, the integrated circuit 200 may be an active component or a passive component.

In some embodiments, the integrated circuit 200 is similar to the integrated circuit 100. Similarly, the integrated circuit 200 includes a circuit region 202 and a seal ring region 204 surrounding the circuit region 202. The integrated circuit 200 includes a semiconductor substrate 220, a device 222, an interconnect structure 224, a seal ring structure SR′ including seal rings 230, 250, alignment marks AM′ and a bonding structure 270. In some embodiments, the semiconductor substrate 220, the device 222, the interconnect structure 224, the seal ring structure SR including the seal rings 230, 250, the alignment marks AM′ and the bonding structure 270 are respectively similar to the semiconductor substrate 120, the device 122, the interconnect structure 124, the seal rings 130, 150, the alignment marks AM and the bonding structure 170 of the integrated circuit 100, so the detailed description thereof is omitted herein.

In some embodiments, the interconnect structure 224 includes at least one insulating layer 226 and a plurality of conductive features 228. In some embodiments, the bonding structure 270 includes at least one bonding dielectric layer 272 and a plurality of bonding conductive features. The bonding conductive features are disposed in the bonding dielectric layer 272 and electrically connected with each other. In some embodiments, the bonding conductive features include bonding vias 274 electrically connected to the interconnect structure 224 and bonding pads 276 electrically connected to the bonding vias 274. The seal rings 230, 250 may include stacks of dummy conductive features 231 such as dummy conductive lines and/or dummy conductive vias. In some embodiments, a shape of the alignment mark AM′ is the same as or different from the alignment mark AM. The shape and configuration of the alignment mark AM′ may be similar to or the same as those of the alignment mark AM, so the detailed description thereof is omitted herein. In some embodiments, a surface (e.g., bottom surface) of the alignment mark AM′ is substantially coplanar with surfaces (e.g., bottom surfaces) of the top conductive feature 228a and the seal rings 230. In some embodiments, the integrated circuit 200 and the integrated circuit 100 are face-to-face bonded together with the bonding structure 170 and the bonding structure 270. In some embodiments, the integrated circuit 200 includes a plurality of conductive pads 280 in the dielectric layer 226. The interconnect structure 224 is disposed between the semiconductor substrate 220 and the conductive pads 280, and the conductive pads 280 are disposed between the bonding structure 270 and the interconnect structure 224, for example. The conductive pads 280 may be disposed adjacent to the top conductive features 228a and the alignment marks AM′. The conductive pads 280 are aluminum pads, for example.

In some embodiments, before the integrated circuit 200 is bonded to the integrated circuit 100, the bonding structure 170 and the bonding structure 270 are aligned by an alignment process, such that the bonding pads 276 are bonded to the bonding pads 176 and the bonding dielectric layer 272 is bonded to the bonding dielectric layer 172. In some embodiments, the alignment process is achieved by using the alignment marks AM, AM′. After the alignment process is achieved, the bonding structure 170 and the bonding structure 270 are bonded together by a hybrid bonding including a metal-to-metal bonding and a dielectric-to-dielectric bonding.

In some embodiments, the integrated circuits 200 is bonded to the integrated circuit 100 by a pick-and-place process using a pick-and-place apparatus. In some embodiments, the alignment marks AM, AM′ of the integrated circuits 100, 200 are used for improved alignment accuracy (e.g., pick-and-place accuracy) of the alignment process. The alignment marks AM, AM′ of the integrated circuits 100, 200 may be used by the pick-and-place apparatus during the pick-and-place process to properly align the integrated circuits 100, 200. For example, before the bonding process between the integrated circuit 100 and the integrated circuit 200, the alignment marks AM of the integrated circuit 100 (e.g., bottom die) are detected to determine a reference position (e.g., pick-and-place center considered by the pick-and-place apparatus) of the integrated circuit 100, and the alignment marks AM′ of the integrated circuit 200 (e.g., top die) are detected to determine a reference position (e.g., physical center) of the integrated circuit 200. Then, the alignment accuracy may be calculated based on a difference between the determined reference position (e.g., pick-and-place center) of the integrated circuit 100 (e.g., bottom die) and the determined reference position (e.g., physical center) of the integrated circuit 200 (e.g., top die). Thus, an overlay shift may be avoided, reduced and/or predictable. However, the disclosure is not limited thereto. The alignment accuracy may be determined by any other suitable method based on the alignment marks AM, AM′ of the integrated circuits 100, 200 according to the algorithm used by the detection method and/or detection device. In some embodiments, by using the alignment marks AM, AM′, undesired shift between the integrated circuits 200 and the integrated circuits 100 and may be reduced or avoided. Moreover, damage due to misalignment may be reduced or avoided.

In some embodiments, during the bonding process of the integrated circuits 200 and the integrated circuit 100, the alignment marks 312a of the carrier 300 may be also used. For example, similar to described above for the bonding between the integrated circuit 100′ and the carrier 300, the alignment marks 312a of the carrier 300 are used for improved alignment accuracy (e.g., pick-and-place accuracy). For example, the alignment marks 312a are detected to determine a reference position (e.g., pick-and-place center considered by the pick-and-place apparatus) of the integrated circuit bonding region 302, and the alignment marks AM′ are detected to determine a reference position (e.g., physical center) of the integrated circuit 200. Then, the alignment accuracy may be calculated based on a difference between the determined reference position (e.g., pick-and-place center) of the integrated circuit bonding region 302 and the determined reference position (e.g., physical center) of the integrated circuit 200. Thus, an overlay shift may be avoided, reduced and/or predictable. However, the disclosure is not limited thereto. The alignment accuracy may be determined by any other suitable method based on the alignment marks AM′ of the integrated circuit 200 according to the algorithm used by the detection method and/or detection device. In some embodiments, by using the alignment marks AM′ and/or the alignment marks 312a, undesired shift of the integrated circuits 200 may be reduced or avoided. Moreover, damage of the integrated circuits 200 due to misalignment may be reduced or avoided.

Referring to FIG. 6E and FIG. 7E, after the integrated circuits 100 and 200 are bonded, a redistribution layer structure 290 is formed over the integrated circuits 100 and 200. The redistribution layer structure 290 includes at least one dielectric layer 292 and at least one conductive layer 294 stacked alternately. The redistribution layer structure 290 is electrically connected to the interconnect structure 224 by through silicon vias (not shown) in the semiconductor substrate 220 of the integrated circuit 200, for example. In some embodiments, the dielectric layer 292 includes a photo-sensitive material such as polybenzoxazole (PBO), polyimide (PI), benzocyclobutene (BCB), a combination thereof or the like. In some embodiments, the conductive layer 294 includes copper, nickel, titanium, a combination thereof or the like. Pads 296 are disposed over the redistribution layer structure 290. In some embodiments, the pads 296 are under bump metallization (UBM) pads for mounting conductive connectors 299, such as metal pillars, μ-bumps or the like. The pads 296 include a metal or a metal alloy. The pads 296 includes aluminum, copper, nickel, or an alloy thereof. The passivation layer 298 covers the dielectric layer 292 and edge portions of the pads 296, and exposes the center portions of the pads 296. In some embodiments, the passivation layer 298 includes silicon oxide, silicon nitride, benzocyclobutene (BCB) polymer, polyimide (PI), polybenzoxazole (PBO) or a combination thereof.

In some embodiments, the formed structure is debonded from the carrier 300. For example, a laser beam may be projected on the release layer 310, so that the release layer 310 is decomposed, releasing the structure thereover. Then, the formed structure is flipped upside down, and is placed on another carrier or tape (not shown), and a singulation process is performed. In some embodiments, the conductive pads 180 are exposed, and then electrically connected to an interconnect structure 410 through a plurality of conductive connectors 412, to form a package 400. The package 400 includes the integrated circuit 100 and the integrated circuit 200 bonded to the integrated circuit 100. The interconnect structure 410 may be a RDL structure, another package, an interposer, a package substrate, a printed circuit board, or the like, and the conductive connectors 412 may be conductive pads, conductive pillars, balls, the like or a combination thereto. The interconnect structure 410 may include conductive connectors 414. The conductive connectors 414 may include solder bumps, and/or may include metal pillars (e.g., copper pillars), solder caps formed on metal pillars, and/or the like.

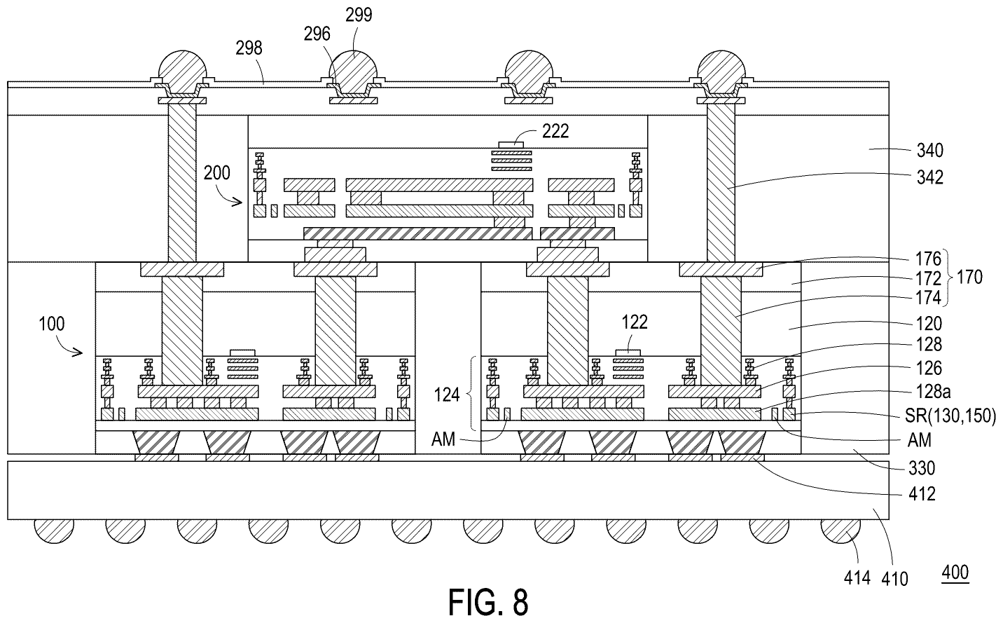

In the illustrated embodiments, the package 400 includes one integrated circuit 100 and one integrated circuit 200. However, the disclosure is not limited thereto. In alternative embodiments, the package 400 may include more than one integrated circuit 100 and/or integrated circuit 200. For example, as shown in FIG. 8, one integrated circuit 200 is bonded to two integrated circuits 100, and adjacent bonding pads 276 of the integrated circuit 200 are bonded to the bonding pads 176 of different integrated circuits 100. In some embodiments, an encapsulant 330 is formed to encapsulate the integrated circuits 100, and an encapsulant 340 is formed to encapsulate the integrated circuit 200. Through vias 342 may be formed in the encapsulant 340 to electrically connect to the redistribution layer structure 290 and the integrated circuits 100. In such embodiments, the alignment marks AM, AM′ are also used during the bonding process of the integrated circuits 100 and 200, to improve the alignment accuracy (e.g., pick-and-place accuracy).

In some embodiments, by using the alignment mark(s) formed between the seal ring in the seal ring corner region, the alignment accuracy (e.g., pick-and-place accuracy) between two elements may be improved. For example, by using the alignment mark(s) disposed adjacent to the L-shaped section and the bridge section, the alignment accuracy of placing an integrated circuit onto a carrier or placing a top integrated circuit onto a bottom integrated circuit is improved. Thus, damage of the integrated circuit due to misalignment may be reduced or avoided, and the yield and performance of the integrated circuit and the package including the integrated circuit may be improved.

In accordance with some embodiments of the disclosure, a structure includes a circuit region, a seal ring region and at least one alignment mark. The seal ring region surrounds the circuit region and includes a seal ring corner region. The seal ring is disposed in the seal ring region, and includes a corner seal ring portion in the seal ring corner region. The corner seal ring portion divides the seal ring corner region into a plurality of sub-regions, and the at least one alignment mark is disposed in at least one of the sub-regions of the seal ring corner region.

In accordance with some embodiments of the disclosure, a structure includes a circuit region, a seal ring and at least one alignment mark. The seal ring surrounds the circuit region. The alignment mark is disposed at an interior corner of the seal ring and separated from the seal ring, wherein the at least one alignment mark has a symmetrical axis substantially perpendicular to a surface of the at least one alignment mark.

In accordance with some embodiments of the disclosure, a structure includes a circuit region, a first seal ring, a plurality of alignment marks and at least one alignment mark. The first seal ring surrounds the circuit region. The alignment marks are disposed at an interior corner of the first seal ring, wherein the alignment marks are separated from each other by the first seal ring therebetween.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a circuit region;
a seal ring region, surrounding the circuit region and comprising a seal ring corner region;
a seal ring disposed in the seal ring region, comprising a corner seal ring portion in the seal ring corner region; and
at least one alignment mark, wherein the corner seal ring portion divides the seal ring corner region into a plurality of sub-regions, and the at least one alignment mark is disposed in at least one of the sub-regions of the seal ring corner region.

2. The semiconductor structure according to claim 1, wherein the at least one alignment mark is separated from the corner seal ring portion.

3. The semiconductor structure according to claim 1, wherein the at least one alignment mark comprises a plurality of alignment marks, and the alignment marks are disposed in the sub-regions respectively.

4. The semiconductor structure according to claim 1, wherein the at least one alignment mark comprises a plurality of alignment marks, and at least two of the alignment marks are disposed in a same sub-region of the sub-regions.

5. The semiconductor structure according to claim 1, wherein the seal ring comprises a main portion forming a substantially rectangular periphery, and the corner seal ring portion comprises:
a bridge section extending between a first edge and a second edge of the main portion; and
an L-shaped section disposed between the main portion and the bridge section and extending between the first edge and the second edge of the main portion.

6. The semiconductor structure according to claim 5, wherein the sub-regions comprise:
a first sub-region between the main portion and the L-shaped section; and
a second sub-region between the L-shaped section and the bridge section.

7. The semiconductor structure according to claim 5, further comprising an additional seal ring surrounding the seal ring and forming an additional substantially rectangular periphery, wherein the main portion of the seal ring is disposed between the corner seal ring portion and the additional seal ring.

8. The semiconductor structure according to claim 1, wherein a shape of the at least one alignment mark comprises a circle, a cross, a rectangle, a pentagon, a hexagon, a flower-like shape or a combination thereof.

9. A structure, comprising:
a circuit region;
a seal ring, surrounding the circuit region; and
at least one alignment mark, disposed at an interior corner of the seal ring and separated from the seal ring, wherein the at least one alignment mark has a symmetrical axis substantially perpendicular to a surface of the at least one alignment mark.

10. The semiconductor structure according to claim 9, wherein the surface of the at least one alignment mark is substantially coplanar with a surface of an interconnect structure in the circuit region and a surface of the seal ring.

11. The semiconductor structure according to claim 9, wherein a shape of the at least one alignment mark comprises a circle, a cross, a regular polygon having at least 3 sides or a combination thereof.

12. The semiconductor structure according to claim 9, wherein the seal ring comprises an L-shaped section separated from the at least one alignment mark.

13. The semiconductor structure according to claim 9, wherein the at least one alignment mark comprises a plurality of alignment marks, and the alignment marks are separated from each other by the seal ring.

14. The semiconductor structure according to claim 9, wherein the at least one alignment mark comprises a dielectric pattern therein.

15. The semiconductor structure according to claim 9, wherein the at least one alignment mark comprises a first alignment mark, a second alignment mark and a third alignment mark, and a distance between the first and second alignment marks is substantially equal to a distance between the first and third alignment marks.

16. The semiconductor structure according to claim 9, wherein the at least one alignment mark comprises a plurality of alignment marks, and the alignment marks have an identical shape.

17. A structure, comprising:
a circuit region;
a first seal ring, surrounding the circuit region; and
a plurality of alignment marks disposed at an interior corner of the first seal ring, wherein the alignment marks are separated from each other by the first seal ring therebetween.

18. The semiconductor structure according to claim 17, wherein the first seal ring comprises a L-shaped section, and the alignment marks are separated from each other by the L-shaped section therebetween.

19. The semiconductor structure according to claim 17, further comprising a second seal ring surrounding the first seal ring.

20. The semiconductor structure according to claim 17, wherein the circuit region comprises a semiconductor substrate, an interconnect structure and a bonding structure, and the alignment marks are disposed over the semiconductor substrate and the bonding structure and disposed adjacent to the interconnect structure.
